(19) United States
(12) Patent Application Publication
(10) Pub. No.: US 2018/0190517 A1
(43) Pub. Date: Jul. 5, 2018

(54) RECIPE SELECTABLE DISPENSE SYSTEM AND METHOD OF OPERATING

(71) Applicant: TEL FSI, Inc., Chaska, MN (US)

(72) Inventors: David DeKraker, Burnsville, MN (US); Jeffrey M. Lauerhaas, Waconia, MN (US); Jeffery W. Butterbaugh, Eden Prairie, MN (US); Alan D. Rose, Wylie, TX (US)

(21) Appl. No.: 15/848,946

(22) Filed: Dec. 20, 2017

Related U.S. Application Data
(60) Provisional application No. 62/440,677, filed on Dec. 30, 2016.

(51) Int. Cl. H01L 21/67

(52) U.S. Cl. CPC H01L 21/67051; H01L 21/6708

(57) ABSTRACT

An apparatus for cleaning a microelectronic workpiece and a method of operating is described. The apparatus includes a workpiece holding mechanism to support and hold a workpiece, a chemical supply mechanism configured to supply multiple chemical fluids including gas-phase components and liquid-phase components, a dispense mechanism arranged to dispense one or more chemical compositions onto the workpiece, and a valve mechanism fluidically disposed between the chemical supply mechanism and the dispense mechanism. A control circuit is coupled to the valve mechanism, and configured to (i) flow at least one gas-phase chemical component to a first nozzle array and at least one liquid-phase chemical component to a second nozzle array, and (ii) flow at least one gas-phase chemical component from the chemical supply mechanism to the second nozzle array and at least one liquid-phase chemical component from the chemical supply mechanism to the first nozzle array.

### CROSS-REFERENCE TO RELATED APPLICATIONS

This application is related to and claims priority to U.S. Provisional Patent Application Ser. No. 62/440,677 filed on Dec. 30, 2016, the entire contents of which are herein incorporated by reference.

### FIELD OF INVENTION

The invention relates to an apparatus and method for wet processing a microelectronic workpiece, and particularly, an apparatus and method for dispensing a fluid onto a microelectronic workpiece during wet cleaning or wet etching.

### BACKGROUND OF THE INVENTION

Integrated circuits (ICs) may be formed on microelectronic substrates, such as semiconductor workpieces, with ever increasing density of active components. The ICs may be formed through successive process treatments that form structures which perform electrical functions as needed. The processing of the microelectronic workpieces may be automated to secure and treat the microelectronic workpiece in a controlled manner. One aspect may include treating a microelectronic workpiece with a wet process solution, e.g., a heated acid solution, to remove material from the workpiece, followed by treating the workpiece with another solution to remove particulate.

To improve yield with conventional approaches, improved fluid dispense systems are necessary to achieve increased material removal rate, damage-free processing, and particle mitigation.

### SUMMARY OF THE INVENTION

Embodiments of the invention relate to an apparatus and method for wet processing a microelectronic workpiece, and particularly, an apparatus and method for dispensing a fluid onto a microelectronic workpiece during wet cleaning or wet etching.

According to one embodiment, an apparatus for wet processing a microelectronic workpiece is described. The apparatus includes a workpiece holding mechanism to support and hold a workpiece, a chemical supply mechanism configured to supply multiple chemical fluids including gas-phase components and liquid-phase components, a dispense mechanism arranged to dispense one or more chemical compositions onto the workpiece, and a valve mechanism fluidically disposed between the chemical supply mechanism and the dispense mechanism. A control circuit is coupled to the valve mechanism, and configured to (i) flow at least one gas-phase chemical component to a first nozzle array and at least one liquid-phase chemical component to a second nozzle array, and (ii) flow at least one gas-phase chemical component from the chemical supply mechanism to the second nozzle array and at least one liquid-phase chemical component from the chemical supply mechanism to the first nozzle array.

According to another embodiment, a method for wet processing a microelectronic workpiece is described. The method includes receiving a workpiece having a surface to be cleaned, placing the workpiece on a workpiece holding mechanism to support and hold a workpiece, supplying chemical fluids from a chemical supply mechanism configured to supply multiple chemical fluids including gas-phase components and liquid-phase components, dispensing supplied chemical fluids from a dispense mechanism including a first independently controllable nozzle array and a second independently controllable nozzle array, controlling a valve mechanism to flow at least one gas-phase chemical component from the chemical supply mechanism to the first nozzle array and at least one liquid-phase chemical component from the chemical supply mechanism to the second nozzle array, and controlling the valve mechanism to flow at least one gas-phase chemical component from the chemical supply mechanism to the second nozzle array and at least one liquid-phase chemical component from the chemical supply mechanism to the first nozzle array.

### BRIEF DESCRIPTION OF THE DRAWINGS

In the accompanying drawings:

FIG. 1 is an illustration of a wet processing chamber according to an embodiment;

FIGS. 2A and 2B provide cross-sections of a dispense system according to another embodiment;

FIG. 3 illustrates a dispense mechanism and dispense mechanism according to the prior art;

FIG. 4 illustrates a dispense mechanism and dispense mechanism according to another embodiment; and

FIG. 5 provides a flow chart illustrating a method for wet processing a microelectronic workpiece according to an embodiment.

### DETAILED DESCRIPTION OF SEVERAL EMBODIMENTS

Apparatus and methods for treating a microelectronic workpiece with a wet process solution including at least one gas-phase component and at least one liquid-phase component to remove material from the workpiece, and treating the workpiece with another solution to remove particulate are described in various embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

“Workpiece” as used herein generically refers to the object being processed in accordance with the invention. The workpiece may include any material portion or structure of a device, particularly a semiconductor or other electronics device, and may, for example, be a base workpiece structure, such as a semiconductor wafer or a layer on or overlying a base workpiece structure such as a thin film. The workpiece may be a conventional silicon workpiece or other bulk workpiece comprising a layer of semi-conductive material. As used herein, the term “bulk workpiece” means and includes not only silicon wafers, but also silicon-on-insulator (“SOI”) workpieces, such as silicon-on-sapphire (“SOS”) workpieces and silicon-on-glass (“SOG”) workpieces, epitaxial layers of silicon on a base semiconductor foundation, and other semiconductor or optoelectronic materials, such as silicon-germanium, germanium, gallium arsenide, gallium nitride, and indium phosphide. The workpiece may be doped or undoped. Thus, workpiece is not intended to be limited to any particular base structure, underlying layer or overlying layer, patterned or un-patterned, patterned, but rather, is contemplated to include any such layer or base structure, and any combination of layers and/or base structures. The description below may reference particular types of workpieces, but this is for illustrative purposes only and not limitation.

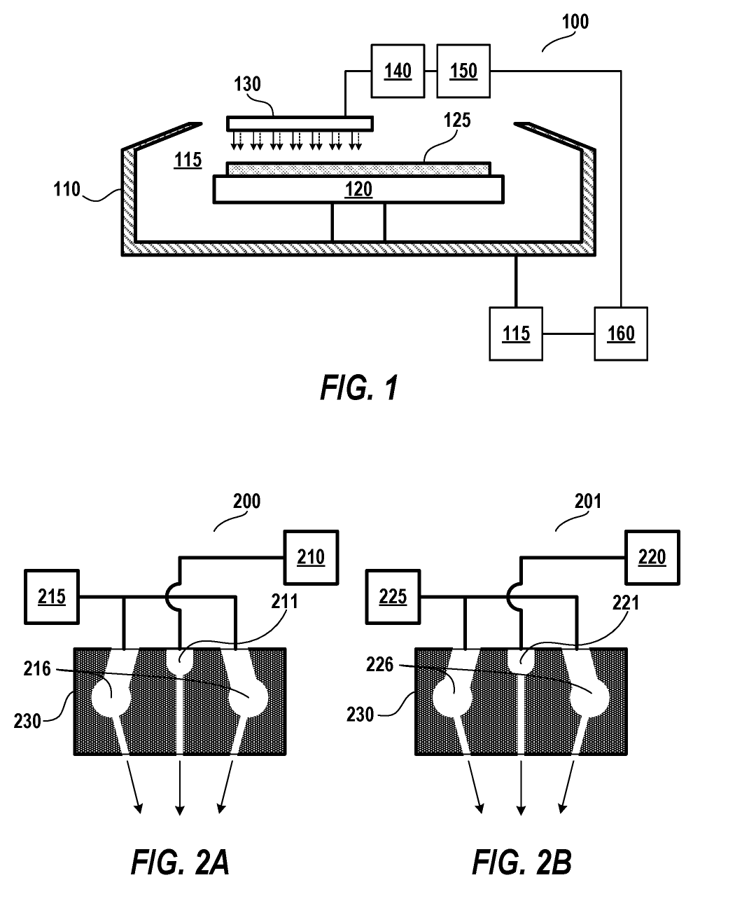

FIG. 1 shows an apparatus for wet processing a microelectronic workpiece according to an embodiment. Wet processing apparatus 100 may be used to perform a wet cleaning or wet etching process on microelectronic workpiece 125. Microelectronic workpiece 125 is supported within a chamber 110 on a workpiece holding mechanism 120, wherein the workpiece holding mechanism 120 can include a rotation mechanism to rotate the workpiece holding mechanism 120. The rotation mechanism can include a spin motor (not shown). This portion of apparatus 100 can correspond to a spray-type or dispense-type wet processing system.

Wet processing systems for single or batch workpiece processing have generally been known, and provide an ability to remove liquids with centrifugal force by spinning or rotating the workpiece(s) on a turntable or carousel, either about their own axis or about a common axis. Exemplary wet processing machines suitable for adaptation in accordance with the present invention are described in U.S. Pat. Nos. 6,406,551 and 6,488,272, which are fully incorporated herein by reference in their entireties. As an example, wet processing machines suitable for adaptation include machines available from TEL FSI, Inc. of Chaska, Minn., e.g., under one or more of the trade designations including ORION™ or ZETA™.

Other examples suitable for adaptation herein are described in U.S. Patent Publication No. 2007/0245954, entitled BARRIER STRUCTURE AND NOZZLE DEVICE FOR USE IN TOOLS USED TO PROCESS MICROELECTRONIC WORKPIECES WITH ONE OR MORE TREATMENT FLUIDS; or as described in U.S. Patent Application Publication No. 2005/0205115, entitled RESIST STRIPPING METHOD AND RESIST STRIPPING APPARATUS or U.S. Patent Application Publication No. 2009/0280235, entitled TOOLS AND METHODS FOR PROCESSING MICROELECTRONIC WORKPIECES USING PROCESS CHAMBER DESIGNS THAT EASILY TRANSITION BETWEEN OPEN AND CLOSED MODES OF OPERATION.

Wet processing apparatus 100 further includes a chemical supply mechanism 150 configured to supply multiple chemical fluids including gas-phase components and liquid-phase components, and a dispense mechanism 130 arranged to dispense one or more chemical compositions onto the workpiece. The dispense mechanism 130 can include a first independently controllable nozzle array and a second independently controllable nozzle array.

As an example, the dispense mechanism 130 can include a bar nozzle assembly oriented in a radial direction from a central portion of the microelectronic workpiece 125 to a peripheral portion of the workpiece that includes both the first nozzle array and the second nozzle array. The bar nozzle assembly has a plurality of nozzles to direct a fluid in gas-phase, or liquid-phase, or combinations thereof onto a surface of microelectronic workpiece 125. The fluid may be dispensed onto microelectronic workpiece in the form of a continuous stream or as aerosol droplets.

In one embodiment, a cross-sectional view of a dispense mechanism 200 is shown in FIG. 2A. Dispense mechanism 200 includes a bar nozzle assembly 230 having an integrally arranged set of orifices in a body that is directed to provide streams that can impinge one another. A first fluid stream is supplied from a first chemical supply mechanism 210 through a first nozzle array 211. A second fluid stream is supplied from a second chemical supply mechanism 215 through a second nozzle array 216. The second fluid stream is angled inward relative to the first fluid stream so as to intersect with the first fluid stream, as shown in FIG. 2A.

The first nozzle array 211 includes plural outlets arranged radially along the span of the bar nozzle assembly from the central portion to the peripheral portion. The second nozzle array 216 includes plural outlets arranged radially along the span of the bar nozzle assembly on opposing sides of the first nozzle array from the central portion to the peripheral portion. The plural outlets of the first nozzle array 211 are oriented to discharge a fluid in a direction substantially parallel to an axis of rotation of the microelectronic workpiece 125. The plural outlets of the second nozzle array 216 are oriented to discharge fluid at an acute angle relative to the axis of rotation of the microelectronic workpiece 125. The plural outlets of the first nozzle array 211 discharge the first fluid stream, and the plural outlets of the second nozzle array 216 are oriented to discharge the second fluid stream inward to intersect and mix with the first fluid stream discharged from the first nozzle array 211. As a result of this impingement, atomization occurs, thereby forming liquid aerosol droplets. While in some circumstances, it may be important to intersect, mix, and atomize fluid streams, other circumstances may require little to no intersection, mixing, and atomization of fluid streams. Such circumstances may facilitate low damage or damage-free processes.

In this embodiment, a liquid-phase component can be flowed to the first nozzle array 211, and a gas-phase component can be flowed to the second nozzle array 216. Such a configuration can be referred as the “single channel liquid” (SCL) dispense mode.

In another embodiment, a cross-sectional view of a dispense mechanism 201 is shown in FIG. 2B. Dispense mechanism 201 includes bar nozzle assembly 230 having an integrally arranged set of orifices in a body that is directed to provide streams that impinge one another. A first fluid stream is supplied from a first chemical supply mechanism 220 through a first nozzle array 221. A second fluid stream is supplied from a second chemical supply mechanism 225 through a second nozzle array 226. The second fluid stream is angled inward relative to the first fluid stream so as to intersect with the first fluid stream, as shown in FIG. 2B.

The first nozzle array 221 includes plural outlets arranged radially along the span of the bar nozzle assembly from the central portion to the peripheral portion. The second nozzle array 226 includes plural outlets arranged radially along the span of the bar nozzle assembly on opposing sides of the first nozzle array from the central portion to the peripheral portion. The plural outlets of the first nozzle array 221 are oriented to discharge a fluid in a direction substantially parallel to an axis of rotation of the microelectronic workpiece 125. The plural outlets of the second nozzle array 226 are oriented to discharge fluid at an acute angle relative to the axis of rotation of the microelectronic workpiece 125. The plural outlets of the first nozzle array 221 discharge the first fluid stream, and the plural outlets of the second nozzle array 226 are oriented to discharge the second fluid stream inward to intersect and mix with the first fluid stream discharged from the first nozzle array 221. As a result of this impingement, atomization occurs, thereby forming liquid aerosol droplets. While in some circumstances, it may be important to intersect, mix, and atomize fluid streams, other circumstances may require little to no intersection, mixing, and atomization of fluid streams. Such circumstances may facilitate low damage or damage-free processes.

According to this embodiment, a gas-phase component can be flowed to the first nozzle array 221, and a liquid-phase component can be flowed to the second nozzle array 226. Such a configuration can be referred as the “dual channel liquid” (DCL) dispense mode.

The SCL and DCL dispense modes can be used to perform various treatments of the microelectronic workpiece 125. As an example, these dispense modes can be used for wet cleaning, wet etching, particle removing, rinsing, drying, etc. During wet cleaning or wet etching, an acid solution can be utilized. The acid solution can include sulfuric acid, phosphoric acid, nitric acid, hydrofluoric acid, variations thereof, mixtures thereof, or mixtures thereof with other agents. For example, the acid solution can include a mixture of sulfuric acid and hydrogen peroxide. Other agents can include water vapor (or steam), nitrogen, oxygen, ozone, etc.

The sulfuric acid composition can include sulfuric acid at a concentration of approximately 96 wt % to approximately 98 wt % (% by weight) sulfuric acid. Furthermore, the sulfuric acid composition can include a mixture containing sulfuric acid and at least one other ingredient. For example, the sulfuric acid composition can further include an oxidizing agent, such as a peroxide (i.e., hydrogen peroxide in a sulfuric acid-hydrogen peroxide mixture, or SPM), ozone or aqueous ozone. Additionally, for example, the hydrogen peroxide can include approximately 30 wt % to 32 wt % aqueous hydrogen peroxide solution.

The sulfuric acid may be heated to a temperature in excess of 70 degrees C., or 150 degrees C., or alternatively, to a temperature in excess of 200 degrees C. For example, the sulfuric acid is heated to a temperature ranging from approximately 70 degrees C. to approximately 220 degrees C. prior to mixing the sulfuric acid with additional material, such as hydrogen peroxide. Additionally, for example, the sulfuric acid is heated to a temperature ranging from approximately 170 degrees C. to approximately 200 degrees C. prior to mixing the sulfuric acid with additional material, such as hydrogen peroxide.

Furthermore, water, such as steam, may be added to the sulfuric acid composition. For example, water or steam can be added to the mixture of sulfuric acid and hydrogen peroxide. Water may be added to the sulfuric acid composition as or after the sulfuric acid composition passes through a dispense nozzle. Additionally, for example, the exposing of the workpiece to the first stripping agent includes dispensing a liquid-phase sulfuric acid composition comprising sulfuric acid and/or its desiccating species and precursors, and exposing the liquid-phase sulfuric acid composition to water vapor in an amount effective to increase the temperature of the liquid-phase sulfuric acid composition above the temperature of the liquid-phase sulfuric acid composition prior to exposure to the water vapor. Furthermore, the substrate may be rotated during the dispensing of the mixed acid stream.

In another embodiment, the one or more process sequences can further include exposing the surface of the workpiece to a second stripping agent containing dilute hydrofluoric acid (dHF). The second stripping agent can include dilute hydrofluoric acid. For example, the dilute hydrofluoric acid can be prepared by diluting concentrated HF solution (e.g., 49 wt % aqueous HF) with water at a dilution ratio of volume parts water to volume parts HF ranging from 50:1 to 1000:1. The dilute hydrofluoric acid can be heated to a temperature ranging from approximately 20 degrees C. to approximately 80 degrees C.

During particle removing, a particle removing agent can be applied, such as an ammonium hydroxide-hydrogen peroxide mixture, SC1, SC2, variations thereof, mixtures thereof, or mixtures thereof with other agents. For example, the cleaning agent can include SC1 composition composed of NH₄OH:H₂O₂:H₂O at a NH₄OH:H₂O₂: H₂O mixture ratio ranging from approximately 1:1:5 to approximately 1:8:500. The mixture ratio expressed above refers to volumetric ratios of approximately 27 wt % to approximately 31 wt % (% by weight) aqueous ammonia solution, approximately 30 wt % to 32 wt % aqueous hydrogen peroxide solution, and water (e.g., the mixture ratio 1:1:5 refers to 1 volume part 27-31 wt % aqueous ammonia solution to 1 volume part 30-32 wt % aqueous hydrogen peroxide solution to 5 volume parts water). The SC1 composition can be adjusted to a temperature in the range of approximately 20 degrees C. to approximately 80 degrees C. Alternatively, or additionally, the cleaning agent can contain a mixture of deionized water, aqueous ammonium hydroxide, and hydrogen chloride to, for example, remove other residue. For example, the cleaning agent can include SC2 composition composed of H₂O₂:HCl:H₂O.

Other agents can include nitrogen, etc. During rinsing and drying, the rinsing and/or drying agent can include water, deionized water, isopropyl alcohol, etc. For example, the rinsing agent can include hydrogen peroxide, deionized (DI) water, hot deionized (HDI) water, cold deionized (CDI) water, a mixture of HDI and CDI, or a mixture of HDI, CDI, and hydrogen peroxide, or any combinations thereof. HDI can include DI water at a temperature of from about 40 degrees C. to about 99 degrees C. CDI can include DI water at a temperature less than about 40 degrees C., or less than about 25 degrees C., or approximately 20 degrees C. 20% by weight, or greater than or equal to 30% by weight, or greater than or equal to 40% by weight.

During wet cleaning or wet etching, the inventors have observed that the removal rate of a material on the microelectronic workpiece 125 can be increased by operating the dispense mechanism 200 in the SCL dispense mode. When operating in the SCL dispense mode, a 33% reduction in liquid component usage, such as acid solution usage, was estimated, and in actuality, a 40% reduction was achieved by reducing both the dispense time and the dispense flow rate.

However, the inventors also observed that while the SCL dispense mode is optimal for a wet etching or wet cleaning step, the DCL dispense mode is optimal for removing particles form an exposed surface of the microelectronic workpiece 125. In the wet etching or wet cleaning step, an acid solution, such as sulfuric acid or sulfuric acid mixture (e.g., sulfuric acid—hydrogen peroxide mixture) is dispensed from the first nozzle array 211, and water vapor is dispensed from the second nozzle array 216. In the particle removal step, nitrogen is dispensed from the first nozzle array 221, and ammonium hydroxide-hydrogen peroxide is dispensed from the second nozzle array 226.

Further yet, the inventors have observed that little to no pre-mixing of currently dispensed chemistry with residual, previously dispensed chemistry within the dispense plumbing, and/or little to no post-mixing or fluid atomization can lead to low damage or damage-free processing. Therefore, gas flow purges of the dispense plumbing, and/or low flow rate gas dispense may be preferred for some processes. For example, SCL sulfuric acid-hydrogen peroxide mixture (SPM) and DCL rinsing (DI water)/SC1 preventing SPM and DI mixing within the SCL dispense path is preferred.

To accommodate the above noted performance, and in order to provide the optimal dispense mode for each step, the configuration of the chemical delivery plumbing to the dispense mechanism was redesigned. This flow path plumbing now allows for switching between the SCL mode, preferable for strip rate, and DCL mode, preferable for particle removal, within a single recipe. While this plumbing enables an increase in strip rate and particle removal efficiency, it introduced new and unforeseen challenges for rinsing and drying of the different flow paths between dispense modes. In particular, it was determined that the simple act of rinsing and drying the flow path can generate residual particles, which can be transferred to the wafer during the final rinsing and drying steps.

The particle generation issue was resolved through optimized sequencing of rinsing, aspiration, and purging, when switching between dispense modes. This optimized sequence can be applied in any liquid dispense equipment that requires rinsing and drying of the flow paths within each integrated recipe.

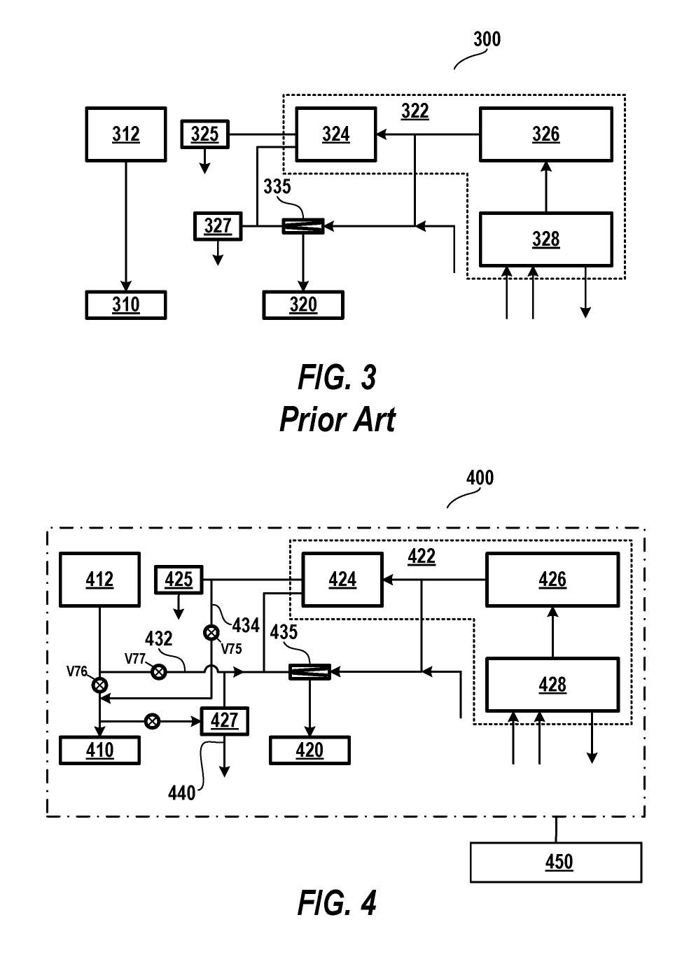

FIG. 3 illustrates a chemical supply arrangement 300 according to the prior art. Chemical supply arrangement 300 includes a first chemical supply mechanism 312 fluidically coupled to a first dispense mechanism 310. Chemical supply arrangement 300 further includes a second chemical supply mechanism 322 fluidically coupled to a second dispense mechanism 320. The first chemical supply mechanism 312 and the second chemical supply mechanism 322, and their respective coupling to the first dispense mechanism 310 and the second dispense mechanism 320 are independent of one another. The first dispense mechanism 310 is supplied a gas-phase component, such as nitrogen or water vapor, from the first chemical supply arrangement 312 through a valve arrangement.

The second dispense mechanism 320 is supplied a liquid-phase component, such as an acid solution (e.g., mixture of sulfuric acid and hydrogen peroxide), from the second chemical supply arrangement 322 through a valve arrangement and mixing tee 335. The second chemical supply arrangement 322 can include a first manifold 324 to supply sulfuric acid, a second manifold 326 to supply other chemistry, such as hydrogen peroxide, ammonium hydroxide, etc., and a third manifold 328 to supply deionized water, for example. Chemical supply arrangement 300 can further include a third dispense mechanism 325, or chemical nozzle, and an aspiration system 327.

The plumbing is arranged in such a manner that the gas-phase component can only be supplied to the first dispense mechanism 310 and the liquid-phase component can only be supplied to the second dispense mechanism 320. Thus, the chemical supply arrangement 300 of FIG. 3 is incapable of achieving the observed performance enhancements described above with reference to wet cleaning and wet etching rate, and particle removal rate.

FIG. 4 illustrates a chemical supply arrangement 400 according to an embodiment. Chemical supply arrangement 400 includes a chemical supply mechanism configured to supply multiple chemical fluids including gas-phase components and liquid-phase components. The chemical supply mechanism includes a first chemical supply mechanism 412 to supply at least one gas-phase component, and a second chemical supply mechanism 422 to supply at least one liquid-phase component. Chemical supply arrangement 400 further includes a dispense mechanism arranged to dispense one or more chemical compositions onto the workpiece, wherein the dispense mechanism includes a first independently controllable nozzle array 410 and a second independently controllable nozzle array 420. Further yet, chemical supply arrangement 400 includes a valve mechanism, having valves V75, V76, and V77, fluidically disposed between the chemical supply mechanism 412, 422 and the dispense mechanism 410, 420.

Chemical supply arrangement 400 includes a control circuit 450 coupled to the valve mechanism, and configured to (i) operably set the valve mechanism to a first valve condition according to a first process recipe that flows at least one gas-phase chemical component from the first chemical supply mechanism 412 to the first nozzle array 410 and at least one liquid-phase chemical component from the second chemical supply mechanism 422 to the second nozzle array 420, and (ii) operably set the valve mechanism 420 to a second valve condition according to a second process recipe that flows at least one gas-phase chemical component from the first chemical supply mechanism 412 to the second nozzle array 420 and at least one liquid-phase chemical component from the second chemical supply mechanism 422 to the first nozzle array 410.

To accommodate the first and second valve condition, at least a first cross-over fluid conduit 432 and a second cross-over fluid conduit 434 are included, together with the valve mechanism that includes valves V75, V76, and V77 to accommodate the added complexity of the manifold plumbing. The additional valve manifolds can include the addition of normally-closed valves, normally-open valves, two-way valves, three-way valves, etc. Chemical supply arrangement 400 further includes an aspiration system 440 to aspirate fluid from the chemical supply arrangement 400

The first chemical supply arrangement 412 can be configured to supply at least one gas-phase component, such as nitrogen or water vapor to either the first nozzle array 410 or the second nozzle array depending upon the valve condition of the valve mechanism. The second chemical supply arrangement 422 can be configured to supply a liquid-phase component, such as an acid solution (e.g., mixture of sulfuric acid and hydrogen peroxide) to either the first nozzle array 410 or the second nozzle array depending upon the valve condition of the valve mechanism. The second chemical supply arrangement 422 can include a first manifold 424 to supply sulfuric acid, a second manifold 426 to supply other chemistry, such as hydrogen peroxide, ammonium hydroxide, etc., and a third manifold 428 to supply deionized water, for example.

Chemical supply arrangement 400 can be configured to operate in SCL or DCL dispense mode. In the SCL and DCL dispense modes, the dispense mechanism includes a spray bar nozzle that has an outlet of the mixing tee plumbed to the second nozzle array 420, which are the center nozzles of spray bar nozzle (e.g., SCL dispense mode) and common port of valve manifold with valves V76 and V78 that are plumbed to the first nozzle array 410, which are the outer nozzles of spray bar nozzle (e.g., DCL) (see FIGS. 2A and 2B).

As an example, a first chemistry including sulfuric acid (H₂SO₄) and hydrogen peroxide (H₂O₂) can be dispensed with steam (i.e. SCL ViPR™). H₂SO₄ is supplied from second chemical supply arrangement 422 to the mixing tee 435, where it is mixed with H₂O₂. The mixture flows to the second nozzle array 420 (i.e., SCL). Steam is supplied from first chemical supply arrangement 412 through valve V76 to the first nozzle array 410.

As another example, a second chemistry including hydrogen peroxide (H₂O₂) and ammonium hydroxide (NH₄OH) can be dispensed with nitrogen as a SC1 treatment of the workpiece (i.e., DCL SC1). A mixture of H₂O₂ and NH₄OH flows from second chemical supply arrangement 422 through valve V75 to the first nozzle array 410 (i.e., DCL). Nitrogen (N₂) is supplied from first chemical supply arrangement 412 through valve V77 and the mixing tee 435 to the second nozzle array 420.

As yet another example, a second chemistry including hydrogen peroxide (H₂O₂) and ammonium hydroxide (NH₄OH) can be dispensed with nitrogen as a SC1 treatment of the workpiece (i.e., SCL SC1). A mixture of H₂O₂ and NH₄OH flows from second chemical supply arrangement 422 through mixing tee 435 to the second nozzle array 420 (i.e., SCL). Nitrogen (N₂) and steam is supplied from first chemical supply arrangement 412 through valve V76 to the first nozzle array 410.

In one embodiment, for an SCL ViPR™ (sulfuric acid and hydrogen peroxide mixture, and steam) and SCL SC1 process (SC1 mixture and nitrogen), the ViPR™ process is dispensed through the second nozzle array 420 (SCL side of the spray bar nozzle) and steam is dispensed through the first nozzle array 410. The SCL dispense path is rinsed between the ViPR™ dispense and the SC1 dispense, and then SC1 is dispensed through the second nozzle array 420 (SCL side of the spray bar nozzle) and nitrogen is dispensed through the first nozzle array 410. The SCL path is rinsed once again after the SC1 dispense and is then aspirated during the final rinse and dry steps.

In another embodiment, for an SCL ViPR™ and DCL SC1 process, the ViPR™ process is dispensed through the second nozzle array 420 (SCL side of the spray bar nozzle) and steam is dispensed through the first nozzle array 410. The SCL path is then rinsed, then cleaned using SC1, then rinsed again, and then switched to nitrogen. The path is not generally aspirated, as aspiration has been observed to lead to an increase of particles under some conditions. When the SCL path switches to nitrogen (i.e., nitrogen flows to the second nozzle array 420), the DCL path switches to liquid (i.e., liquid-phase component, water, SC1, etc., flows to the first nozzle array 410). The DCL will first dispense water, then switch to SC1. As a result, the SC1 can be atomized by nitrogen through the SCL path. After the SC1 dispense, the path is rinse and the aspirated during the final rinse and dry steps.

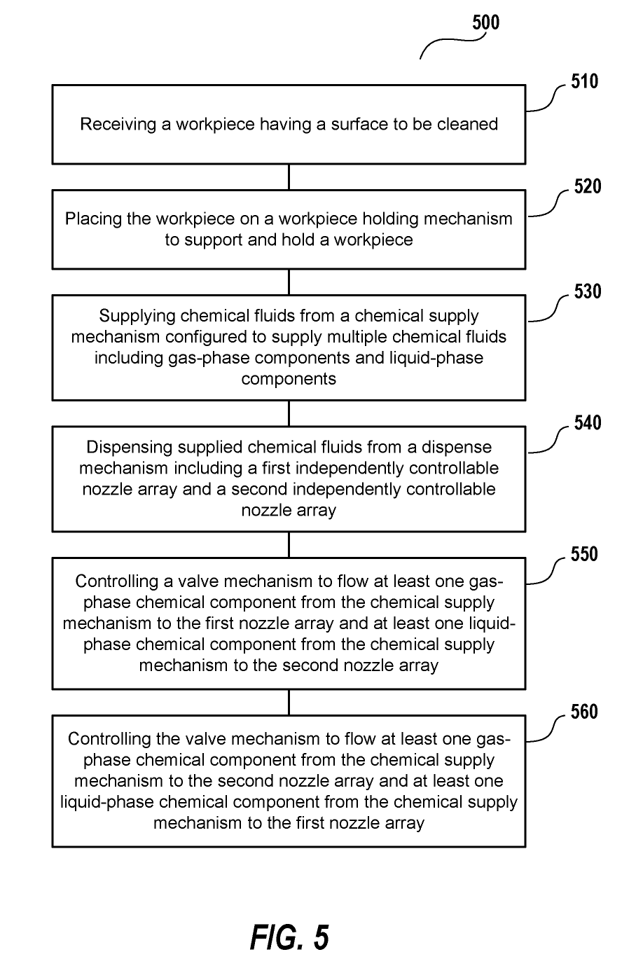

Referring now to FIG. 5, a method for wet processing a microelectronic workpiece is described according to another embodiment. The method includes receiving a workpiece having a surface to be cleaned (in 510), placing the workpiece on a workpiece holding mechanism to support and hold a workpiece (in 520), supplying chemical fluids from a chemical supply mechanism configured to supply multiple chemical fluids including gas-phase components and liquid-phase components (in 530), dispensing supplied chemical fluids from a dispense mechanism including a first independently controllable nozzle array and a second independently controllable nozzle array (in 540), controlling a valve mechanism to flow at least one gas-phase chemical component from the chemical supply mechanism to the first nozzle array and at least one liquid-phase chemical component from the chemical supply mechanism to the second nozzle array (in 550), and controlling the valve mechanism to flow at least one gas-phase chemical component from the chemical supply mechanism to the second nozzle array and at least one liquid-phase chemical component from the chemical supply mechanism to the first nozzle array (in 560). The method further includes rinsing the plumbing and aspirating the plumbing, as described above.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

1. An apparatus for wet processing a microelectronic workpiece, comprising:
a workpiece holding mechanism to support and hold a workpiece;
a chemical supply mechanism configured to supply multiple chemical fluids including gas-phase components and liquid-phase components;
a dispense mechanism arranged, and configured to dispense one or more chemical compositions onto the workpiece, the dispense mechanism including a first independently controllable nozzle array and a second independently controllable nozzle array;
a valve mechanism fluidically disposed between the chemical supply mechanism and the dispense mechanism; and
a control circuit coupled to the valve mechanism, and configured to (i) operably set the valve mechanism to a first valve condition according to a first process recipe that flows at least one gas-phase chemical component from the chemical supply mechanism to the first nozzle array and at least one liquid-phase chemical component from the chemical supply mechanism to the second nozzle array, and (ii) operably set the valve mechanism to a second valve condition according to a second process recipe that flows at least one gas-phase chemical component from the chemical supply mechanism to the second nozzle array and at least one liquid-phase chemical component from the chemical supply mechanism to the first nozzle array.

2. The apparatus of claim 1, wherein the dispense mechanism further comprises a third independently controllable nozzle array.

3. The apparatus of claim 1, further comprising:
a rotation mechanism coupled to the workpiece holding mechanism, and configured to rotate the workpiece.

4. The apparatus of claim 3, wherein the dispense mechanism comprises a bar nozzle assembly oriented in a radial direction from a central portion of the workpiece to a peripheral portion of the workpiece that includes both the first nozzle array and the second nozzle array.

5. The apparatus of claim 4, wherein the first nozzle array includes plural outlets arranged radially along the span of the bar nozzle assembly from the central portion to the peripheral portion.

6. The apparatus of claim 5, wherein the second nozzle array includes plural outlets arranged radially along the span of the bar nozzle assembly on opposing sides of the first nozzle array from the central portion to the peripheral portion.

7. The apparatus of claim 6, wherein the plural outlets of the first nozzle array are oriented to discharge a fluid in a direction substantially parallel to an axis of rotation of the workpiece.

8. The apparatus of claim 7, wherein the plural outlets of the second nozzle array are oriented to discharge fluid at an acute angle relative to the axis of rotation of the workpiece.

9. The apparatus of claim 8, wherein the plural outlets of the first nozzle array discharge a first fluid, and the plural outlets of the second nozzle array are oriented to discharge a second fluid inward to intersect and mix with the first fluid discharged from the first nozzle array.

10. The apparatus of claim 1, wherein the first valve condition flows an acid solution to the first nozzle array, and water vapor to the second nozzle array.

11. The apparatus of claim 10, wherein the acid solution is a mixture of sulfuric acid and hydrogen peroxide.

12. The apparatus of claim 10, wherein the second valve condition flows an inert gas to the first nozzle array, and a cleaning composition to the second nozzle array.

13. The apparatus of claim 12, the inert gas includes nitrogen or a noble gas.

14. The apparatus of claim 12, wherein the cleaning composition includes SC1, SC2, or an ammonia-peroxide water (APM) solution.

15. The apparatus of claim 1, wherein the control circuit is programmably instructed to perform the first valve condition, followed by the second valve condition when processing a workpiece.

16. A method of wet processing a microelectronic workpiece, comprising:
receiving a workpiece having a surface to be cleaned;
placing the workpiece on a workpiece holding mechanism to support and hold a workpiece;
supplying chemical fluids from a chemical supply mechanism configured to supply multiple chemical fluids including gas-phase components and liquid-phase components;
dispensing supplied chemical fluids from a dispense mechanism including a first independently controllable nozzle array and a second independently controllable nozzle array;
controlling a valve mechanism disposed between the chemical supply mechanism and the dispense mechanism by operably setting the valve mechanism to a first valve condition according to a first process recipe that flows at least one gas-phase chemical component from the chemical supply mechanism to the first nozzle array and at least one liquid-phase chemical component from the chemical supply mechanism to the second nozzle array; and
controlling the valve mechanism by operably setting the valve mechanism to a second valve condition according to a second process recipe that flows at least one gas-phase chemical component from the chemical supply mechanism to the second nozzle array and at least one liquid-phase chemical component from the chemical supply mechanism to the first nozzle array.

17. The method of claim 16, further comprising:
rotating the workpiece.

18. The method of claim 16, further comprising:
removing material from the workpiece during the dispensing.

19. The method of claim 16, wherein the first valve condition flows a mixture of sulfuric acid and hydrogen peroxide to the first nozzle array, and water vapor to the second nozzle array.

20. The method of claim 19, wherein the second valve condition flows nitrogen to the first nozzle array, and SC1 to the second nozzle array.
